(19) United States
(12) Patent Application Publication
(10) Pub. No.: US 2025/0383387 A1
(43) Pub. Date: Dec. 18, 2025

(54) ELECTROSTATIC DETECTOR

(71) Applicant: ALPS ALPINE CO., LTD., Tokyo (JP)

(72) Inventors: Shotaro ASAKURA, Miyagi (JP); Hayato MIYAGAWA, Gwangju (KR); Tomoya SASAKI, Miyagi (JP); Shigeyuki TENMA, Miyagi (JP); Masaru ONOSE, Unterschleissheim (DE); Satoru TAKIZAWA, Tokyo (JP); Atsushi OTA, Tokyo (JP)

(21) Appl. No.: 19/316,290

(22) Filed: Sep. 2, 2025

Related U.S. Application Data
(63) Continuation of application No. PCT/JP2024/002151, filed on Jan. 25, 2024.

(30) Foreign Application Priority Data
Mar. 17, 2023 (JP) 2023-043466

(51) Int. Cl. G01R 29/12

(52) U.S. Cl. CPC G01R 29/12

(57) ABSTRACT

An electrostatic detector includes a plurality of sensor electrodes, a shield electrode coupled to the plurality of sensor electrodes, a signal output unit configured to output an AC signal, a plurality of first interconnects coupled to the plurality of sensor electrodes, respectively, a plurality of second interconnects configured to couple the shield electrode to the signal output unit and supply the AC signal to the shield electrode, the plurality of second interconnects having mutually different resistance values between the shield electrode and the signal output unit, and a determination unit coupled to the plurality of sensor electrodes via the plurality of first interconnects and configured to determine whether or not an abnormality is generated in a second interconnect of the plurality of second interconnects based on electrostatic capacitances of the plurality of sensor electrodes.

### CROSS-REFERENCE TO RELATED APPLICATIONS

This application is a continuation application of International Application No. PCT/JP2024/002151 filed on Jan. 25, 2024 and designated the U.S., which is based upon and claims priority to Japanese Patent Application No. 2023-043466, filed on Mar. 17, 2023, the entire contents of which are incorporated herein by reference.

### BACKGROUND OF THE INVENTION

### 1. Field of the Invention

The present disclosure relates to electrostatic detectors.

### 2. Description of the Related Art

There is an electrostatic capacitance detector capable of determining a disconnection of a part of a plurality of interconnects to a shield electrode, by detecting a phase difference between a detection signal from a plurality of detection electrodes and a drive signal (sinusoidal signal) (refer to Japanese Laid-Open Patent Publication No. 2021-190990, for example).

However, the conventional electrostatic capacitance detector (electrostatic detector) does not determine which interconnect of the plurality of interconnects to the shield electrode includes an abnormality, such as the disconnection or the like.

### SUMMARY OF THE INVENTION

Accordingly, one object of the present disclosure is to provide an electrostatic detector capable of determining which interconnect of a plurality of interconnects to a shield electrode includes an abnormality, such as the disconnection or the like.

An electrostatic detector according to an embodiment of the present disclosure includes a plurality of sensor electrodes; a shield electrode coupled to the plurality of sensor electrodes; a signal output unit configured to output an AC signal; a plurality of first interconnects coupled to the plurality of sensor electrodes, respectively; a plurality of second interconnects configured to couple the shield electrode to the signal output unit and supply the AC signal to the shield electrode, the plurality of second interconnects having mutually different resistance values between the shield electrode and the signal output unit; and a determination unit coupled to the plurality of sensor electrodes via the plurality of first interconnects and configured to determine whether or not an abnormality is generated in a second interconnect of the plurality of second interconnects based on electrostatic capacitances of the plurality of sensor electrodes.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a diagram illustrating an example of a configuration of an electrostatic detector according to an embodiment;

FIG. 2 is a diagram illustrating an example of a circuit configuration of the electrostatic detector according to the embodiment;

FIG. 3 is a diagram illustrating in detail an example of a circuit configuration corresponding to one sensor electrode;

FIG. 4 is a diagram illustrating an example of changes in a real signal and an imaginary signal depending on a state of the electrostatic detector of the embodiment;

FIG. 5 is a diagram illustrating simulation results (part 1);

FIG. 6A is diagram illustrating simulation results (part 2);

FIG. 6B is a diagram illustrating the simulation results (part 2);

FIG. 6C is a diagram illustrating the simulation results (part 2); and

FIG. 7 is a flow chart illustrating an example of a process performed by an electrostatic detector 100.

### DESCRIPTION OF THE PREFERRED EMBODIMENTS

Hereinafter, embodiments applied with an electrostatic detector according to the present disclosure will be described.

### EMBODIMENTS

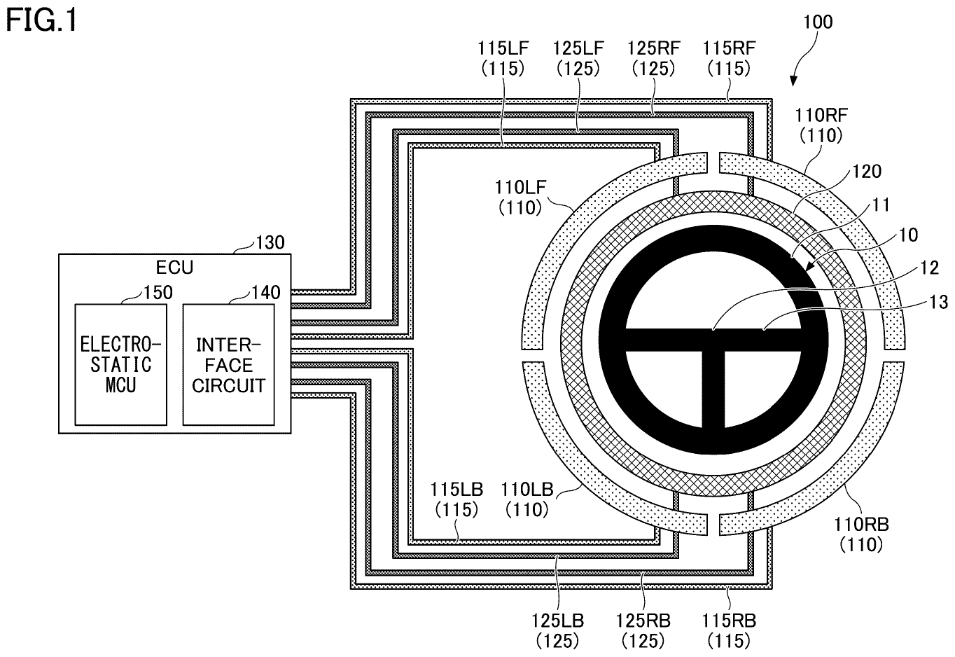

FIG. 1 is a diagram illustrating an example of a configuration of an electrostatic detector 100 according to an embodiment. FIG. 1 illustrates a state where the electrostatic detector 100 is provided on a steering wheel 10 of a vehicle, for example.

The steering wheel 10 is provided in the vehicle, and sensor electrodes 110 and a shield electrode 120 of the electrostatic detector 100 are provided on an inner side of an outer skin (cover) of a rim 11. In addition, the rim 11 is formed in an annular shape, and a core metal formed of a metal material, such as iron or the like, is provided in an annular shape over an entire circumference on the inner side of the outer skin. The electrostatic detector 100 determines whether or not a hand H of a driver is in contact with the rim 11 of the steering wheel 10. The hand H is an example of a detection target. The electrostatic detector 100 determines whether or not an abnormality, such as a disconnection or the like, is generated in interconnects 125 to the shield electrode 120. The annular rim 11 of the steering wheel 10 is an example of a fixation target to which the sensor electrodes 110 and the shield electrode 120 are fixed. The example of the fixation target is not limited to the annular rim 11 of the steering wheel 10, and may be a part that has a shape other than an annular shape and is gripped by the hand H, such as a control stick of an aircraft, for example. The disconnection or the like of the interconnects 125 is not limited to the case of a complete break of the interconnects 125, and includes a case where an impedance changes due to a crack or the like in the interconnects 125. Hereinafter, each of these states of the interconnects 125 is simply referred to as an abnormality in the interconnects 125.

Hereinafter, the driver of the vehicle is referred to as an operator of the electrostatic detector 100. The electrostatic detector 100 that determines whether or not an abnormality is generated in the interconnects 125, and determines whether or not the hand H of the operator as a detection target is in contact with the outer skin of the rim 11 of the steering wheel 10 provided with the sensor electrodes 110, will be described. Touching the rim 11 of the steering wheel 10 provided with the sensor electrodes 110 by the hand H of the operator will be referred to as an operation of the operator.

The steering wheel 10 includes the rim 11, a hub 12, and spokes 13. In FIG. 1, the sensor electrode 110 and the shield electrode 120 are illustrated outside the rim 11 for the sake of convenience to make the sensor electrodes 110 and the shield electrode 120 visible.

A ground terminal of the steering wheel 10 is electrically connected to the core metal of the rim 11 of the steering wheel 10. By connecting the core metal and a ground terminal of an ECU 130 via a connector that is not illustrated, a ground potential of the ECU 130 becomes equal to a ground potential of the steering wheel 10.

### <Configuration of Electrostatic Detector 100>

The electrostatic detector 100 includes the sensor electrodes 110, the shield electrode 120, and the electronic control unit (ECU) 130. The ECU 130 includes an interface circuit 140 and an electrostatic microcontroller unit (MCU) 150. The interface circuit 140 is connected to the sensor electrodes 110 and the shield electrode 120 via interconnects 115 and 125, respectively. The interconnects 115 are an example of at least a part of first interconnects, and the interconnects 125 are an example of at least a part of second interconnects. The interconnects 115 are a portion of the first interconnect located outside the ECU 130, and the interconnects 125 are a portion of the second interconnect located outside the ECU 130.

### <Sensor Electrodes 110>

Four sensor electrodes 110 are disposed in left-right and front-rear directions of the rim 11 of the steering wheel 10, and include sensor electrodes 110LF, 110LB, 110RF, and 110RB. A description will be made using the left-right direction and the up-down direction in FIG. 1. Because FIG. 1 illustrates the steering wheel 10 as viewed from the operator (driver), the left-right direction and the up-down direction in FIG. 1 correspond to the left-right direction and the up-down direction of the vehicle, respectively. In addition, a direction perpendicularly penetrating FIG. 1 corresponds to a front-rear direction of the vehicle. Moreover, in the description of the sensor electrode 110 or the like, the left-right direction and the up-down direction refer to the left-right direction and the up-down direction of the steering wheel 10 in a state where a steering angle of the vehicle is in a neutral state.

The sensor electrodes 110LF, 110LB, 110RF, and 110RB are disposed in the left-right and front-rear directions around the rim 11. The sensor electrodes 110LF, 110LB, 110RF, and 110RB are disposed on the left front (LF) side, the left rear (LB) side, the right front (RF) side, and the right rear (RB) side of the rim 11, respectively.

In FIG. 1, the sensor electrodes 110LF, 110LB, 110RF, and 110RB are illustrated outside around the rim 11 so as to facilitate understanding of connection relationships with the interconnects 115 and 125 which will be described later. However, in actual practice, the sensor electrode 110LF is located on the front side of a left half of the circumference of the rim 11, and the sensor electrode 110LB is located on the rear side of the left half of the circumference of the rim 11. The sensor electrode 110RF is located on the front side of a right half of the circumference of the rim 11, and the sensor electrode 110RB is located on the rear side of the right half of the circumference of the rim 11.

The sensor electrodes 110LF, 110LB, 110RF, and 110RB are provided to overlap the shield electrode 120 over approximately the entire circumference of the rim 11 of the steering wheel 10, in a state where the sensor electrodes 110LF, 110LB, 110RF, and 110RB are insulated from the core metal of the rim 11 of the steering wheel 10.

The sensor electrodes 110LF, 110LB, 110RF, and 110RB are connected to the ECU 130 via interconnects 115LF, 115LB, 115RF, and 115RB, respectively. The sensor electrodes 110LF, 110LB, 110RF, and 110RB are band shaped film electrodes provided over approximately the entire circumference of the annular rim 11, and can be manufactured by coating a conductor, such as a silver paste or the like, onto surfaces of resin films, for example.

In addition, the interconnects 115LF, 115LB, 115RF, and 115RB are signal lines, and constitute four wire harnesses in a state where the interconnects 115LF, 115LB, 115RF, and 115RB are wrapped and shielded by interconnects 125LF, 125LB, 125RF, and 125RB which will be described later, respectively.

In the following, the sensor electrodes 110LF, 110LB, 110RF, and 110RB are simply referred to as sensor electrodes 110 when not particularly distinguishing the sensor electrodes 110LF, 110LB, 110RF, and 110RB from one another. Similarly, the interconnects 115LF, 115LB, 115RF, and 115RB are simply referred to as interconnects 115 when not particularly distinguishing the interconnects 115LF, 115LB, 115RF, and 115RB from one another.

### <Shield Electrode 120>

The shield electrode 120 is provided over approximately the entire circumference of the annular rim 11 of the steering wheel 10, in a state where the shield electrode 120 is insulated from the core metal of the rim 11 and from the sensor electrodes 110. Similar to the sensor electrodes 110, the shield electrode 120 is a band shaped film electrode, and is provided over approximately the entire circumference of the rim 11 of the steering wheel 10 in a state where the shield electrode 120 overlaps the sensor electrodes 110.

The shield electrode 120 is provided to reduce noise by shielding the sensor electrodes 110 from structures having a ground potential in the vehicle, and to reduce parasitic capacitances between the sensor electrodes 110 and the structures having the ground potential. The shield electrode 120 is supplied with an AC signal from an AC signal source which will be described later, and functions as an active shield electrode. By causing the shield electrode 120 to function as the active shield electrode, the functions of reducing the noise and reducing the parasitic capacitances (hereinafter referred to as an active shielding function) can be obtained.

The four interconnects 125LF, 125LB, 125RF, and 125RB are connected to the shield electrode 120. The number of the interconnects 125LF through 125RB is equal to the number of the sensor electrodes 110LF through 110RB and the number of the interconnects 115LF through 115RB. The interconnects 125LF, 125LB, 125RF, and 125RB are connected to the left front (LF), left rear (LB), right front (RF), and right rear (RB) of the shield electrode 120, respectively.

The shield electrode 120 is connected to the ECU 130 via the interconnects 125LF, 125LB, 125RF, and 125RB. The band shaped film electrode used for the shield electrode 120 can be produced by coating a conductor, such as a silver paste or the like, on a surface of a resin film, for example.

The interconnects 125LF, 125LB, 125RF, and 125RB have a configuration that wraps and shields the interconnects 115LF, 115LB, 115RF, and 115RB as signal lines, respectively, for example. The interconnects 125LF, 125LB, 125RF, and 125RB shield the interconnects 115LF, 115LB, 115RF, and 115RB, respectively, in such a relationship that the interconnects 115LF through 115RB correspond to core wires of coaxial cables and the interconnects 125LF through 125RB correspond to the shielded wires of the coaxial cables. The interconnect 115LF and the interconnect 125LF constitute one wire harness, and the interconnect 115LB and the interconnect 125LB constitute one wire harness. The interconnect 115RF and the interconnect 125RF constitute one wire harness, and the interconnect 115RB and the interconnect 125RB constitute one wire harness.

By supplying the AC signal to the shield electrode 120 described above, a parasitic capacitance with a structure other than the hand H to be detected can be reduced, and a flow of a current from the sensor electrode 110 to other than the hand H can be suppressed, thereby improving a detection accuracy to detect contact by the detection target.

In the following description, the interconnects 125LF, 125LB, 125RF, and 125RB are simply referred to as interconnects 125 when not particularly distinguishing the interconnects 125LF, 125LB, 125RF, and 125RB from one another.

The number of the interconnects 125 is equal to the number of the interconnects 115, for example. For this reason, by disposing a portion where the interconnect 125LF is connected to the shield electrode 120 and a portion where the interconnect 115LF is connected to the sensor electrode 110LF close to each other, the interconnect 115LF can easily be shielded by the interconnect 125LF. The same applies to the interconnects 125LB through 125RB and the interconnects 115LB through 115RB. Accordingly, the interconnects 115LF through 115RB can easily be shielded by the interconnects 125LF through 125RB, respectively.

In addition, the interconnects 125LF, 125LB, 125RF, and 125RB are connected to the left front (LF), the left rear (LB), the right front (RF), and the right rear (RB) of the shield electrode 120, respectively. For this reason, when an abnormality is generated in one of the interconnects 125LF through 125RB, an abnormality is generated in the active shielding function with respect to one of the sensor electrodes 110LF through 110RB. Because the interconnects 125LF through 125RB shield the interconnects 115LF through 115RB, respectively, the abnormality is generated in the active shielding function when the abnormality is generated in the interconnects 125LF through 125RB and the abnormality is generated in the shielding of the interconnects 115LF through 115RB. The abnormality in the active shielding function is a deviation from an ideal active shielding state.

### <ECU 130>

The ECU 130 is provided inside an instrument panel of the vehicle, for example. The ECU 130 includes an interface circuit 140 and an electrostatic MCU 150.

### <Interface Circuit 140>

The interface circuit 140 is connected to the sensor electrodes 110LF through 110RB and the shield electrode 120, via the interconnects 115LF through 115RB and the interconnects 125LF through 125RB, respectively. The interface circuit 140 inputs sine waves (input sine waves) to the sensor electrodes 110 and the shield electrode 120 based on a command input from the electrostatic MCU 150, and acquires sine waves (output sine waves) output from the sensor electrodes 110LF through 110RB. The interface circuit 140 acquires capacitance values (electrostatic capacitances) of the sensor electrodes 110LF through 110RB from the input sine waves and the output sine waves, performs a digital conversion and a noise reduction by a lowpass filter or the like, to output the capacitance values as amplitude AD conversion values to the electrostatic MCU 150. The amplitude AD conversion values are represented by a counter value having no unit, for example. In addition, the amplitude AD conversion value is a value representing a difference from a predetermined reference value representing a noise floor.

### <Electrostatic MCU 150>

The electrostatic MCU 150 is implemented by a computer including a central processing unit (CPU), a random access memory (RAM), a read only memory (ROM), an input/output interface, an internal bus, or the like. As an example, an ECU (not illustrated) that controls electronic devices in the vehicle provided with the steering wheel 10 is connected to the electrostatic MCU 150. The ECU of the vehicle may be an electronic device related to an autonomous driving of the vehicle, for example.

The electrostatic MCU 150 includes a determination unit 151 and a memory 152. The determination unit 151 is a functional block representing a function of a program executed by the electrostatic MCU 150. Further, the memory 152 functionally represents a memory of the electrostatic MCU 150.

The determination unit 151 determines whether or not the hand H of the driver is in contact with the rim 11 of the steering wheel 10, and determines whether or not an abnormality, such as a disconnection or the like, is generated in the interconnects 125. Details of a determination process performed by the determination unit 151 will be described later.

The memory 152 stores programs, data, or the like required for the determination unit 151 to perform the determination process.

### <Circuit Configuration>

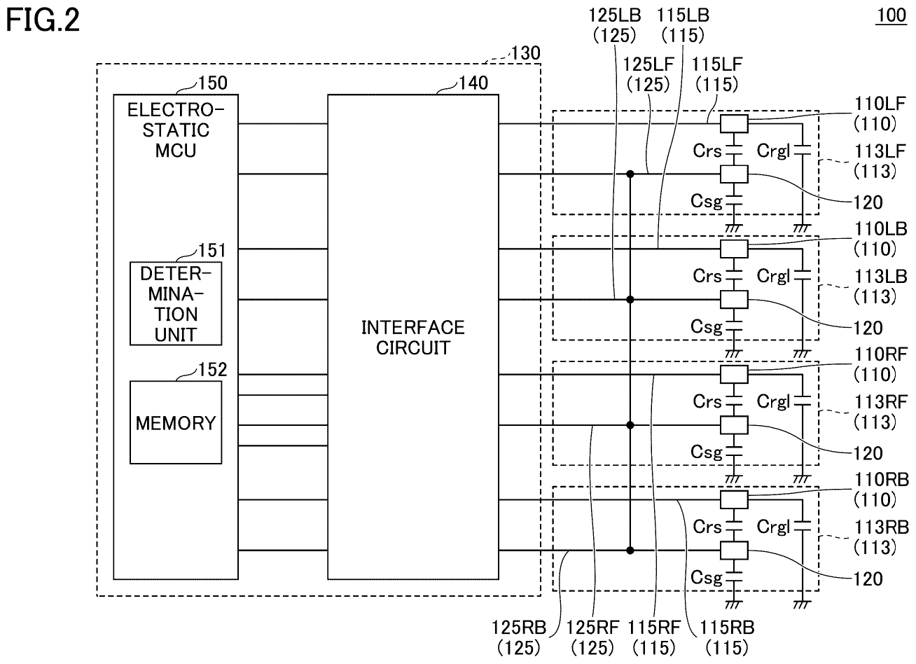

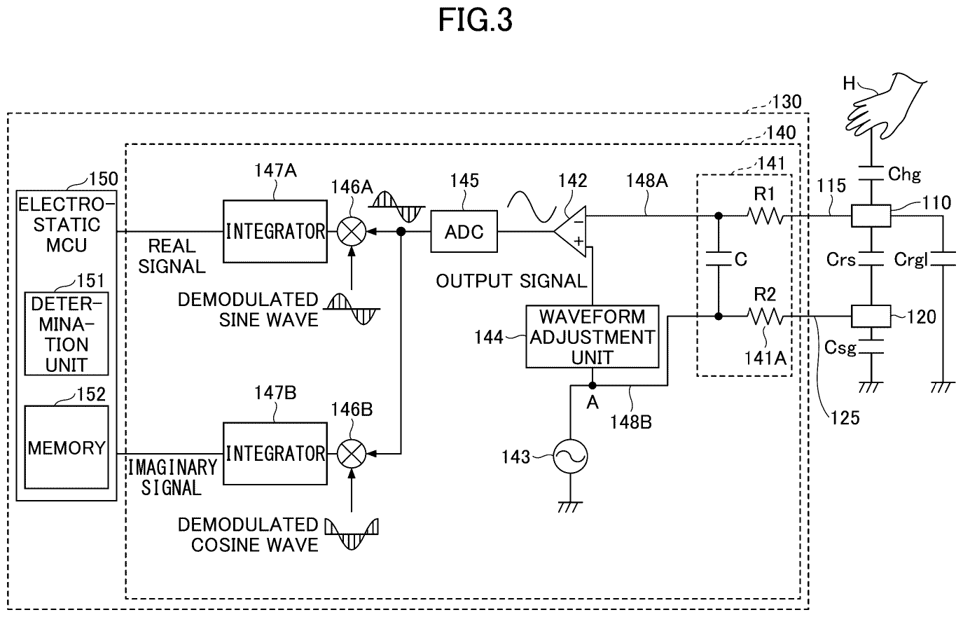

Next, a circuit configuration of the electrostatic detector 100 will be described. The following description will be made with reference to FIG. 2 and FIG. 3, in addition to FIG. 1. FIG. 2 is a diagram illustrating an example of the circuit configuration of the electrostatic detector 100. FIG. 3 is a diagram illustrating in detail an example of a circuit configuration corresponding to the sensor electrode 110.

### <Sensor Electrodes 110 and Shield Electrode 120>

FIG. 2 illustrates circuits 113LF through 113RB of four sensor electrodes 110LF through 110RB, four interconnects 115LF through 115RB, one shield electrode 120, and four interconnects 125LF through 125RB.

The circuit 113LF includes the sensor electrode 110LF, the interconnect 115LF, the shield electrode 120, and the interconnect 125LF, and the circuit 113LB includes the sensor electrode 110LB, the interconnect 115LB, the shield electrode 120, and the interconnect 125LB. The circuit 113RF includes the sensor electrode 110RF, the interconnect 115RF, the shield electrode 120, and the interconnect 125RF, and the circuit 113RB includes the sensor electrode 110RB, the interconnect 115RB, the shield electrode 120, and the interconnect 125RB. Although one shield electrode 120 is illustrated in divisions inside the four circuits 113LF through 113RB in FIG. 2, the shield electrode 120 is a single electrode, and thus, the shield electrodes 120 inside the circuits 113LF through 113RB are connected to one another. Hereinafter, the circuits 113LF through 113RB are referred to as circuits 113 when not particularly distinguishing the circuits 113LF through 113RB from one another. FIG. 3 illustrates in detail the example of the configuration of the circuit 113.

The ground (ground potential point) in the circuits of FIG. 2 and FIG. 3 is a portion of the ground potential, such as a body or the like of the vehicle, and has the same potential as the core metal of the steering wheel 10. The ground potential is an example of a reference potential, and the ground potential point is an example of a reference potential point. FIG. 3 also illustrates the hand H of the operator.

An electrostatic capacitance between the hand H and the sensor electrode 110 is denoted by Chg, an electrostatic capacitance between the sensor electrode 110 and the shield electrode 120 is denoted by Crs, an electrostatic capacitance (stray capacitance) between the sensor electrode 110 and the ground is denoted by Crgl, and an electrostatic capacitance between the shield electrode 120 and the ground is denoted by Csg.

### <Interface Circuit 140>

The interface circuit 140 includes a filter circuit 141, a charge amplifier 142, an AC signal source 143, a waveform adjustment unit 144, an analog-to-digital converter (ADC) 145, a multiplier 146A, a multiplier 146B, an integrator 147A, an integrator 147B, and interconnects 148A and 148B. The interface circuit 140 can be implemented by an integrated circuit (IC) chip, for example. The AC signal source 143 is an example of a signal output unit. As an example, an embodiment in which the interface circuit 140 includes the multiplier 146A, the multiplier 146B, the integrator 147A, and the integrator 147B will be described. However, the multiplier 146A, the multiplier 146B, the integrator 147A, and the integrator 147B may be included in the electrostatic MCU 150.

In addition, although four circuits 113LF through 113RB are illustrated in FIG. 2, the configurations of the four circuits 113LF through 113RB are the same, and thus, the configuration of the circuit 113 illustrated in FIG. 3 will be described below.

### <Filter Circuit 141>

The filter circuit 141 is an RC lowpass filter provided between the sensor electrode 110 and the shield electrode 120 on one side, and an inverting input terminal of the charge amplifier 142 and a connection point A between the AC signal source 143 and the waveform adjustment unit 144 on the other side. In actual practice, four filter circuits 141 corresponding to the circuits 113LF through 113RB illustrated in FIG. 2 are provided.

The filter circuit 141 is composed of resistors R1 and R2 and a capacitor C, for example. The capacitor C is connected between the inverting input terminal of the charge amplifier 142 and the connection point A between the AC signal source 143 and the waveform adjustment unit 144. The resistor R1 is inserted in series between the sensor electrode 110 and one end (an upper terminal in FIG. 2 and FIG. 3) of the capacitors C. The resistor R2 is inserted in series between the shield electrode 120 and the other end (a lower terminal in FIG. 2 and FIG. 3) of the capacitor C.

The resistor R2 may be referred to as a resistor 141A. The resistor R1 is a portion of the interconnect 148A, and the resistor R2 (resistor 141A) is a portion of the interconnect 148B. The filter circuit 141 uses the resistor R1, which is a portion of the interconnect 148A, and the resistor R2 (resistor 141A), which is a portion of the interconnects 148B, as resistive components of the RC lowpass filter. The resistance values of the resistors 141A of the four filter circuits 141 included in the interface circuit 140 are mutually different. The reason for the mutually different resistance values will be described later.

### <Charge Amplifier 142>

The charge amplifier 142 has a non-inverting input terminal (+) that is connected to the waveform adjustment unit 144, the inverting input terminal (−) that is connected to one end (the upper terminal) of the capacitor C and the resistor R1 of the filter circuit 141, and an output that is connected to the ADC 145. The inverting input terminal (−) of the charge amplifier 142 is an example of a first terminal, and the non-inverting input terminal (+) of the charge amplifier 142 is an example of a second terminal. The charge amplifier 142 is a differential amplifier that amplifies a difference between an input to the non-inverting input terminal (+) and an input to the inverting input terminal (−), and outputs an output signal of the amplified difference.

### <AC Signal Source 143>

The AC signal source 143 outputs an AC signal for driving the shield electrode 120. An output terminal of the AC signal source 143 is connected to the other end (the lower terminal) of the capacitor C and the resistor 141A of the filter circuit 141, and to an input terminal of the waveform adjustment unit 144, so that the AC signal is supplied to the shield electrode 120 via the filter circuit 141 and to the waveform adjustment unit 144. Because the shield electrode 120 is electromagnetically coupled to the sensor electrode 110, the AC signal is also supplied to the sensor electrode 110. The sensor electrode 110 and the shield electrode 120 are supplied with in-phase AC signals.

Although the configuration in which the AC signal source 143 is connected to the shield electrode 120 via the filter circuit 141 is described in this embodiment, the positions of the sensor electrode 110 and the shield electrode 120 may be reversed. In this case, the AC signal output from the AC signal source 143 is supplied to the sensor electrode 110 via the filter circuit 141, and is supplied to the shield electrode 120 via the sensor electrode 110.

### <Waveform Adjustment Unit 144>

The waveform adjustment unit 144 adjusts the amplitude and phase of the AC signal supplied from the AC signal source 143 and outputs the adjusted AC signal, so that a voltage of the output signal of the charge amplifier 142 becomes approximately zero in an initial state when the hand H or the like of the operator is not in contact with the rim 11. Even after the adjustment is performed in the initial state, the waveform adjustment unit 144 maintains the adjusted state of the amplitude and phase of the AC signal, and continues to output the AC signal to the non-inverting input terminal (+) of the charge amplifier 142.

### <ADC 145>

ADC 145 has an input terminal connected to the output terminal of charge amplifier 142, and an output terminal connected to one input terminal of each of the multipliers 146A and 146B. The ADC 145 converts the signal output from the charge amplifier 142 into a digital signal, and outputs the digital signal to the multipliers 146A and 146B.

### <Multiplier 146A>

The multiplier 146A has the one input terminal connected to the output terminal of the ADC 145, the other input terminal input with a demodulated sine wave, and an output terminal connected to the integrator 147A. The phase of the demodulated sine wave input to the other input terminal is adjusted so as to be in-phase with the AC signal output from the AC signal source 143. The multiplier 146A multiplies the output of the ADC 145 (the signal obtained by digitally converting the signal output from the charge amplifier 142) by the AC signal as the demodulated sine wave to demodulate the digitally converted signal, thereby generating a signal according to an amplitude of an AC component having the same frequency as the AC signal output from the AC signal source 143, and outputting the generated signal to the integrator 147A. The AC signal as the demodulated sine wave is an example of a first AC signal.

### <Multiplier 146B>

The multiplier 146B has the one input terminal connected to the output terminal of the ADC 145, the other input terminal input with a demodulated cosine wave, and an output terminal connected to the integrator 147B. The phase of the demodulated cosine wave input to the other input terminal is adjusted so as to differ by 90 degrees (is advanced by 90 degrees) with respect to the AC signal output from the AC signal source 143. The multiplier 146B multiplies the output of the ADC 145 (digitally converted signal of the output signal of the charge amplifier 142) by the AC signal as the demodulated cosine wave, thereby generating a signal according to an amplitude of an AC component having a 90 degree phase difference from the AC signal output from the AC signal source 143, and outputting the generated signal to the integrator 147B. The AC signal as the demodulated cosine wave is an example of a second AC signal.

### <Integrator 147A>

The integrator 147A has an input terminal connected to the output terminal of the multiplier 146A, and an output terminal connected to one input terminal of the electrostatic MCU 150, and integrates the output of the multiplier 146A to output the integrated signal to the electrostatic MCU 150 as a real signal. The real signal represents a counter value obtained by integrating the output of the multiplier 146A. The real signal is an example of a first conversion value, and is input to the electrostatic MCU 150.

### <Integrator 147B>

The integrator 147B has an input terminal connected to the output terminal of the multiplier 146B, and an output terminal connected to the other input terminal of the electrostatic MPU 150, and integrates the output of the multiplier 146B to output the integrated signal to the electrostatic MCU 150 as an imaginary signal. The imaginary signal represents a counter value obtained by integrating the output of the multiplier 146B. The imaginary signal is an example of a second conversion value, and is input to the electrostatic MCU 150.

### <Interconnect 148A>

The interconnect 148A includes the resistor R1 inserted in series, and connects the interconnect 115 and the non-inverting input terminal of the charge amplifier 142. The resistor R1 is a portion of the interconnect 148A. The interconnect 115 and the interconnect 148A are an example of a first interconnect. The interconnect 115 is connected to the sensor electrode 110, and the interconnect 148A is connected to the electrostatic MPU 150 via the charge amplifier 142, the ADC 145, the multipliers 146A and 146B, and the integrators 147A and 147B.

### <Interconnect 148B>

The interconnect 148B includes the resistor R2 (resistor 141A) inserted in series, and connects the interconnect 125 and the AC signal source 143. The resistor R2 (resistor 141A) is a portion of the interconnect 148B. The interconnect 125 and the interconnect 148B are an example of a second interconnect that connects the shield electrode 120 and the AC signal source 143.

### <Determination Unit 151>

The determination unit 151 illustrated in FIG. 1 determines whether or not an abnormality, such as a disconnection or the like, in the interconnect 125, based on the real signal and the imaginary signal, and determines whether or not the detection target is in contact with the outer skin of the steering wheel 10. The details of the determination process will be described later.

### <Real Signal and Imaginary Signal>

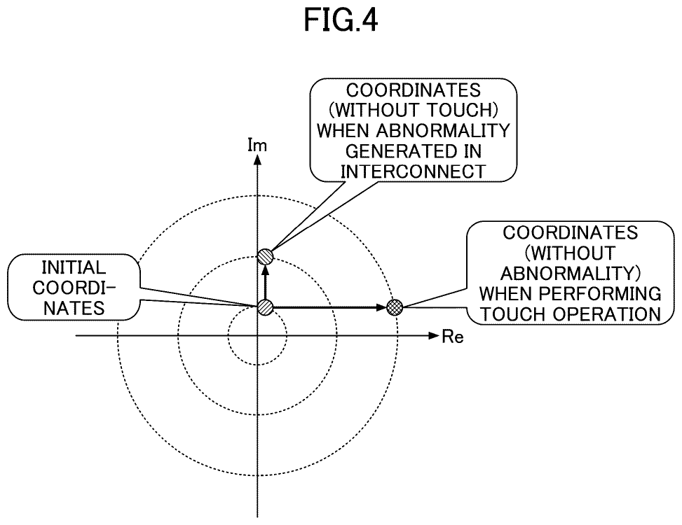

FIG. 4 is a diagram illustrating an example of changes in the real signal and the imaginary signal depending on a state of the electrostatic detector 100. In FIG. 4, the abscissa indicates a real axis Re, and the ordinate indicates an imaginary axis Im. Coordinates determined by the real signal and the imaginary signal of the electrostatic detector 100 can be set as illustrated in FIG. 4, for example, according to the state of the electrostatic detector 100, by adjusting an impedance or the like of various parts of the circuits 113LF through 113RB.

In FIG. 4, initial coordinates are located approximately on the imaginary axis Im, and are positioned very close to an origin. At such initial coordinates, values of the real signal and the imaginary signal are extremely small. The initial coordinates are coordinates obtained in an initial state of the electrostatic detector 100. The initial state refers to a state in which an abnormality, such as a disconnection or the like, is not generated in the interconnects 125, and the hand H is not in contact with the outer skin of the steering wheel 10. The initial coordinates can be obtained by adjusting the impedance or the like of various parts of the circuits 113LF through 113RB.

In addition, the coordinates (without abnormality) at a time when a touch operation is performed are coordinates that are obtained when the touch operation is performed in a state in which no abnormality such as the disconnection or the like is generated in the interconnects 125. The time when the touch operation is performed refers to a state where the hand H is in contact with the outer skin of the steering wheel 10 (a state where the touch operation is performed). The coordinates (without abnormality) at the time when the touch operation is performed are coordinates at which the value of the real signal is extremely large and the value of the imaginary signal is extremely small. That is, the coordinates at the time when the touch operation is performed are the coordinates that are obtained by increasing mostly only the value of the real signal as compared to the initial state. By adjusting the impedance or the like of various parts of the circuits 113LF through 113RB, it is possible to obtain the coordinates (without abnormality) at the time when the touch operation is performed.

In addition, the coordinates (without touch) at the time when the abnormality is generated in the interconnects 125 refer to coordinates that are obtained in a state where no touch operation is performed and an abnormality, such as the disconnection or the like, is generated in the interconnects 125 of the electrostatic detector 100. The coordinates (without touch) at the time when the abnormality is generated in the interconnects 125 are coordinates at which the value of the real signal is extremely small and the value of the imaginary signal is extremely large. That is, the coordinates at the time when the abnormality is generated are the coordinates that are obtained by increasing mostly only the value of the imaginary signal as compared to the initial state. By adjusting the impedance or the like of various parts of the circuits 113LF through 113RB, it is possible to obtain the coordinates (without touch) at the time when the abnormality is generated in the interconnects 125.

<Setting of Resistance Values of Resistors 141A of Circuits 113LF through 113RB>

As illustrated in FIG. 4, the coordinates (with touch) at the time when no abnormality is generated in the interconnects 125 can be distinguished from the coordinates (without touch) at the time when no abnormality is generated in the interconnects 125. Similarly, it may be regarded that the coordinates in the state where the touch operation is performed at the time when the abnormality is generated in the interconnects 125 can be distinguished from the coordinates (without touch) at the time when the abnormality is generated in the interconnects 125.

The electrostatic detector 100 determines whether or not an abnormality, such as a disconnection or the like, is generated in one of the interconnects 125LF through 125RB, by setting the resistance values of the resistors 141A connected to the circuits 113LF through 113RB to mutually different values. In this case, an embodiment in which the resistance values of the four resistors 141A connected to the circuits 113LF through 113RB are set to mutually different values will be described. However, instead of setting the resistance values of the resistors 141A to mutually different values, resistance values of four interconnects 148B connected to the circuits 113LF through 113RB may be set to mutually different values, for example. For example, the resistance values of the four interconnects 148B may be set to mutually different values by making line widths, thicknesses, materials, or the like of the four interconnects 148B mutually different.

### <Simulation Results (Part 1)>

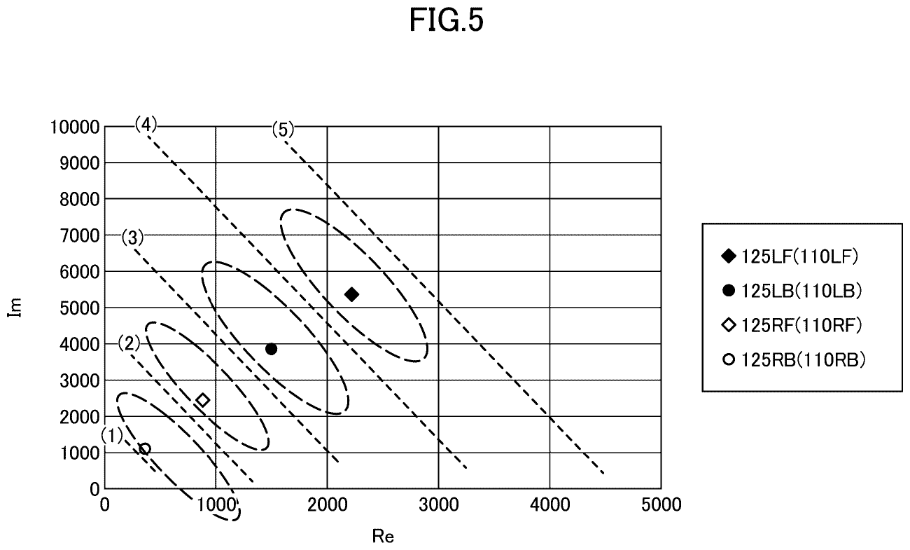

FIG. 5 is a diagram illustrating simulation results (part 1). FIG. 5 illustrates an example of the simulation results for coordinates (without touch) at the time when the abnormality is generated in the interconnects 125. In FIG. 5, the abscissa indicates the value (counter value) of the real signal, and the ordinate indicates the value (counter value) of the imaginary signal. FIG. 5 illustrates the coordinates (without touch) at the time when the abnormality is generated in the interconnects 125LF through 125RB by setting the resistance values of the resistors 141A of the circuits 113LF through 113RB to 200 Ω, 250 Ω, 350Ω, and 677Ω, respectively, for example.

The real signal and the imaginary signal in the case where the abnormality is generated in each of the interconnects 125LF through 125RB are the real signal and the imaginary signal obtained in the interface circuit 140 illustrated in FIG. 3 connected to each of the circuits 113LF through 113RB. That is, the real signal and the imaginary signal in the case where the abnormality is generated in the interconnect 125LF are the real signal and the imaginary signal obtained in the interface circuit 140 illustrated in FIG. 3 connected to the circuit 113LF. The real signal and the imaginary signal in the case where the abnormality is generated in the interconnect 125LB are the real signal and the imaginary signal obtained in the interface circuit 140 illustrated in FIG. 3 connected to the circuit 113LB. The same applies to the interconnects 125RF and 125RB.

In FIG. 5, the real signal and the imaginary signal in the case where the abnormality is generated in the interconnect 125LF are indicated by white circular marks (∘), and the real signal and the imaginary signal in the case where the abnormality is generated in the interconnect 125LB are indicated by black circular marks (•). Further, the real signal and the imaginary signal in the case where the abnormality is generated in the interconnect 125RF are indicated by white diamond shaped marks (⋄), and the real signal and the imaginary signal in the case where the abnormality is generated in the interconnect 125LB are indicated by black diamond shaped marks (♦).

In this example, the interconnects 125LF, 125LB, 125RF, and 125RB shield the interconnects 115LF, 115LB, 115RF, and 115RB connected to the sensor electrodes 110LF, 110LB, 110RF, and 110RB, respectively. For this reason, the generation of an abnormality in the interconnect 125LF corresponds to the generation of an abnormality in the active shielding function with respect to the sensor electrode 110LF. Similarly, the generation of an abnormality in the interconnect 125LB corresponds to the generation of an abnormality in the active shielding function with respect to the sensor electrode 110LB. The generation of an abnormality in the interconnect 125RF corresponds to the generation of an abnormality in the active shielding function with respect to the sensor electrode 110RF. The generation of an abnormality in the interconnect 125RB corresponds to the generation of an abnormality in the active shielding function with respect to the sensor electrode 110RB.

Because the resistance values of the resistors 141A of the circuits 113LF through 113RB are mutually different, when an abnormality, such as a disconnection or the like, is generated in each of the interconnects 125LF through 125RB, as illustrated in FIG. 5, the values of the real signals and the imaginary signals become mutually different. The four marks illustrated in FIG. 5 indicate examples of the values of the real signals and the imaginary signals when the abnormality is generated in each of the interconnects 125LF through 125RB.

The values of the real signal and the imaginary signal indicate the smallest values when the abnormality is generated in the interconnect 125LF, and indicate the second smallest values when the abnormality is generated in the interconnect 125LB. The values of the real signals and the imaginary signals indicate the third smallest values (second largest values) when the abnormality is generated in the interconnect 125RF, and indicate the largest values when the abnormality is generated in the interconnect 125RB.

Impedances of the interconnects 125LF through 125RB vary depending on the state of the disconnection. As an example, in a case where the resistance values of the resistors 141A of the circuits 113LF through 113RB are varied by ±10%, ranges in which the values of the real signals and the imaginary signals can vary due to the abnormality in each of the interconnects 125LF through 125RB are indicated by four elliptical broken lines.

The four elliptical broken lines are separated by straight lines (1) through (5), and there is no overlap among the four elliptical broken lines. For this reason, by using the straight lines (1) through (5), it is possible to determine the interconnects 125LF through 125RB in which the abnormality is generated.

The resistance values of the resistors 141A of the circuits 113LF through 113RB may be set to values that enable determination of whether or not an abnormality, such as a disconnection or the like, is generated in one of the interconnects 125LF through 125RB, using the straight lines (1) through (5).

By determining whether or not the abnormality, such as the disconnection or the like, is generated in one of the interconnects 125LF, 125LB, 125RF, and 125RB, it is possible to determine whether or not an abnormality is generated in the active shielding function with respect to one of the sensor electrodes 110LF, 110LB, 110RF, and 110RB.

In this example, the simulation results for the case where the resistance values of the resistors 141A of the circuits 113LF through 113RB are set to 200 Ω, 250 Ω, 350Ω, and 677Ω, respectively, is described. The resistance values of 200 Ω, 250 Ω, 350Ω, and 677Ω are values obtained by calculation so that an equivalent resistance value is 75Ω, for example. However, the resistance values of the resistors 141A of actual circuits 113LF through 113RB may be set to appropriate values that can determine whether or not the abnormality, such as the disconnection or the like, is generated in one of the interconnects 125LF, 125LB, 125RF, and 125RB, by taking into consideration the impedances of various parts of the actual circuits 113LF through 113RB, the impedance of the interface circuit 140, or the like.

### <Simulation Results (Part 2)>

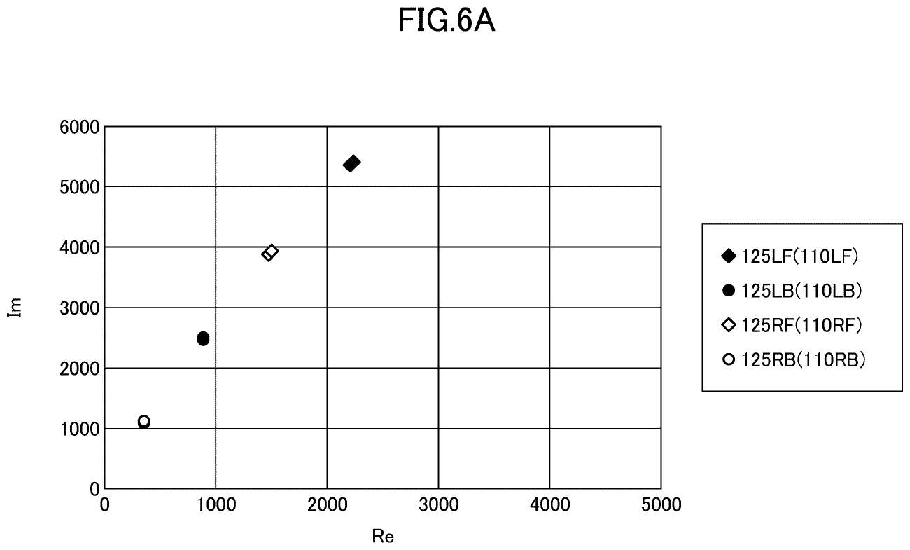

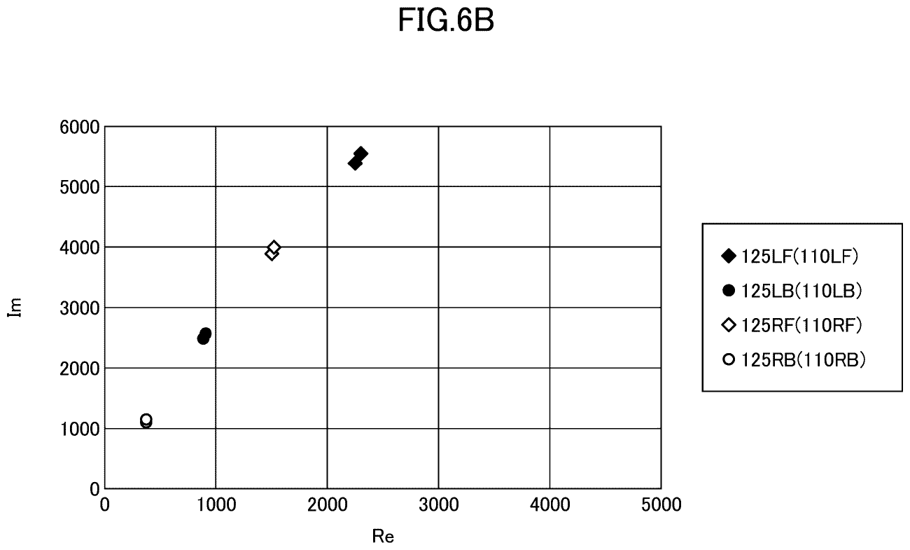

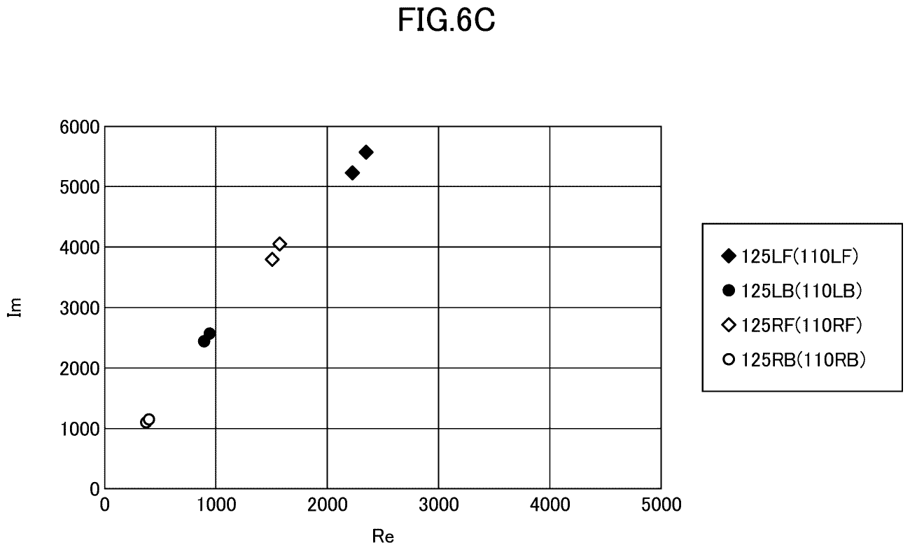

FIG. 6A through FIG. 6C are diagrams illustrating simulation results (part 2). FIG. 6A through FIG. 6C illustrate examples of the simulation results for coordinates (with touch) at the time when the abnormality is generated in the interconnects 125. The coordinates (with touch) at the time when the abnormality is generated in the interconnects 125 are coordinates in a state where a touch operation is performed at the time when the abnormality is generated in the interconnects 125. FIG. 6A through FIG. 6C illustrate the coordinates (with touch) at the time when the abnormality is generated in the interconnects 125 by setting the resistance values of the resistors 141A of the circuits 113LF through 113RB to 200 Ω, 250 Ω, 350Ω, and 677Ω, respectively, for example.

FIG. 6A through FIG. 6C indicate the coordinates obtained by the values of the real signals and the imaginary signals obtained by four interface circuits 140 (refer to FIG. 3) connected to the circuits 113LF through 113RB when a failure occurs in each of the interconnects 125LF through 125RB. That is, in the case where a failure occurs in the interconnect 125LF, the coordinates obtained by the values of the real signals and the imaginary signals obtained by the four interface circuits 140 (refer to FIG. 3) connected to the circuits 113LF through 113RB are illustrated. The same applies to the interconnects 125RF through 125RB. That is, 16 coordinates are illustrated in each of FIG. 6A through FIG. 6C.

In FIG. 6A through FIG. 6C, the real signals and the imaginary signals obtained by the four interface circuits 140 when an abnormality is generated in the interconnect 125LF are indicated by white circular marks (∘), and the real signals and the imaginary signals obtained by the four interface circuits 140 when an abnormality is generated in the interconnect 125LB are indicated by black circular marks (•). In addition, the real signals and the imaginary signals obtained by the four interface circuits 140 when an abnormality is generated in the interconnect 125RF are indicated by white diamond shaped marks (⋄), and the real signals and the imaginary signals obtained by the four interface circuits 140 when an abnormality is generated in the interconnect 125LB are indicated by black diamond shaped marks (♦).

FIG. 6A illustrates an example of the coordinates for the case where the abnormality is generated in each of the interconnects 125LF through 125RB in a state where two fingers touch the outer skin of the rim 11 of the steering wheel 10. As illustrated in FIG. 6A, when the abnormality is generated in the interconnect 125LF, the coordinates obtained by the four interface circuits 140 are all approximately the same coordinates. Similarly, when the abnormality is generated in the interconnects 125LB through 125RB, the coordinates obtained by the four interface circuits 140 are all approximately the same coordinates.

The coordinates for the case where the abnormality is generated in each of the interconnects 125LF through 125RB were completely divided into four groups. Accordingly, it was found that it is possible to determine the interconnects 125LF through 125RB in which the abnormality is generated, using the coordinates obtained by any one of the four interface circuits 140 in a state where the two fingers touch the outer skin of the rim 11 of the steering wheel 10.

FIG. 6B illustrates an example of the coordinates for the case where the abnormality, such as the disconnection or the like, is generated in each of the interconnects 125LF through 125RB in a state where one hand grips (touches) the outer skin of the steering wheel 10 at the two o'clock position. In FIG. 6B, similar to the results illustrated in FIG. 6A, the coordinates obtained by the four interface circuits 140 when the abnormality is generated in the interconnect 125LF are all substantially the same coordinates. In addition, the coordinates obtained by the four interface circuits 140 for the interconnects 125LB through 125RB were all approximately the same coordinates although slight variations were observed when compared to the coordinates in FIG. 6A.

The coordinates for the case where the abnormality is generated in each of the interconnects 125LF through 125RB were completely divided into four groups. Accordingly, it was found that it is possible to determine the interconnects 125LF through 125RB in which the abnormality is generated, using the coordinates obtained by any one of the four interface circuits 140 in a state where one hand grips (touches) the outer skin of the steering wheel 10.

FIG. 6C illustrates an example of the coordinates for the case where the abnormality, such as the disconnection or the like, is generated in each of the interconnects 125LF through 125RB in a state where both hands grip (touch) the outer skin of the steering wheel 10 at the 10 o'clock and the 2 o'clock positions. In FIG. 6C, similar to the results illustrated in FIG. 6A, the coordinates obtained by the four interface circuits 140 when the abnormality is generated in the interconnect 125LF are all substantially the same coordinates. In addition, the coordinates obtained by the four interface circuits 140 for the interconnects 125LB through 125RB are all approximately the same coordinates, similar to the case of FIG. 6A.

The coordinates for the case where the abnormality is generated in each of the interconnects 125LF through 125RB were completely divided into four groups. Accordingly, it was found that it is possible to determine the interconnects 125LF through 125RB in which the abnormality is generated, using the coordinates obtained by any one of the four interface circuits 140 in a state where both hands grip (touch) the outer skin of the steering wheel 10.

### <Flow Chart>

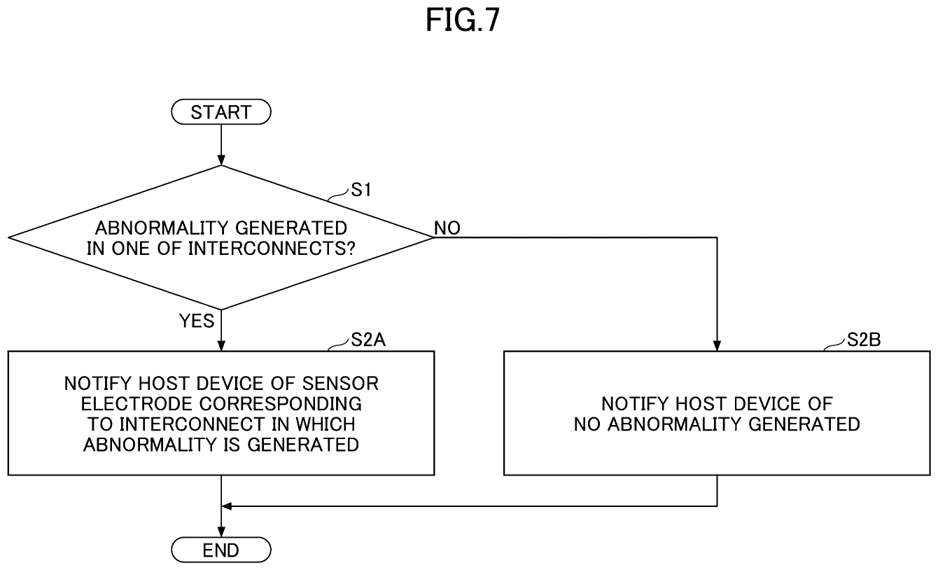

FIG. 7 is a flow chart illustrating an example of a process performed by the electrostatic detector 100. In this example, the process for a case where the determination unit 151 determines whether or not an abnormality is generated in one of the interconnects 125LF through 125RB, based on the real signal and the imaginary signal output from one of the four interface circuits 140 will be described. However, it is possible to determine whether or not the abnormality is generated in one of the interconnects 125LF through 125RB, based on the real signals and the imaginary signals output from two or more interface circuits 140 among the four interface circuits 140.

When the process is started, the determination unit 151 determines whether or not an abnormality is generated in one of the interconnects 125LF through 125RB (step S1).

When the determination unit 151 determines that an abnormality is generated in one of the interconnects 125LF through 125RB (S1: YES), the determination unit 151 specifies the sensor electrode 110 corresponding to the interconnect in which the abnormality is generated, and notifies a host device that an abnormality is generated in the active shielding function with respect to the specified sensor electrode 110 (step S2A). The sensor electrode 110LF corresponds to the interconnect 125LF, and the sensor electrode 110LB corresponds to the interconnect 125LB. The sensor electrode 110RF corresponds to the interconnect 125RF, and the sensor electrode 110RB corresponds to the interconnect 125RB.

When the determination unit 151 determines that no abnormality is generated in any of the interconnects 125LF through 125RB (S1: NO), the determination unit 151 notifies the host device that no abnormality is generated (step S2B).

When the process of step S2A or S2B ends, the determination unit 151 ends the series of processes (END).

As an example, the determination unit 151 repeatedly performs the process illustrated in FIG. 7 at a predetermined control cycle, during a period from a time when an ignition or a power supply of the vehicle mounted with the electrostatic detector 100 is turned on until a time when the ignition or the power supply is turned off. In addition, the determination unit 151 determines whether or not the hand H is in contact with the rim 11 of the steering wheel 10, based on the real signal and the imaginary signal output from at least one interface circuit 140 among the four interface circuits 140.

### <Advantageous Features>

The electrostatic detector 100 includes a plurality of sensor electrodes 110, a shield electrode 120 coupled to the plurality of sensor electrodes 110, an AC signal source 143 that outputs an AC signal, a plurality of first interconnects (115, 148A) connected to the plurality of sensor electrodes 110, a plurality of second interconnects (125, 148B) that connect the shield electrode 120 and the AC signal source 143 and supply the AC signal to the shield electrode 120, the plurality of second interconnects (125, 148B) having mutually different resistance values between the shield electrode 120 and the AC signal source 143, and a determination unit 151 that is connected to the plurality of sensor electrodes 110 via the plurality of first interconnects (115, 148A) and determines whether or not an abnormality is generated in one of the plurality of second interconnects (125, 148B), based on electrostatic capacitances of the plurality of sensor electrodes 110.

Accordingly, it is possible to provide the electrostatic detector 100 capable of determining the interconnect 125 in which an abnormality, such as a disconnection or the like, is generated among the plurality of interconnects 125 connected to the shield electrode 120.

In addition, at least a part (the interconnects 125) of the second interconnects (125, 148B) may be a shield interconnect that shields at least a part (the interconnects 115) of the first interconnects (115, 148A). In this case, the interconnects 125 can shield the interconnects 115 from noise, thereby improving the noise resistance.

The number of the second interconnects (125, 148B) may be equal to the number of the first interconnects (115, 148A). In this case, the portion of the interconnect 125LF connected to the shield electrode 120 and the portion of the interconnect 115LF connected to the sensor electrode 110LF can be disposed close to each other, so that the interconnect 115LF can easily be shielded by the interconnect 125LF. The same applies to the interconnects 125LB through 125RB and the interconnects 115LB through 115RB. In addition, it is possible to determine an abnormality generated in the active shielding function with respect to the sensor electrodes 110 connected to the interconnects 115 corresponding to the interconnects 125 in which the abnormality is generated.

Moreover, at least a part (125) of the second interconnects (125, 148B) may shield the first interconnects (115, 148A) by covering at least a part (115) of the first interconnects (115, 148A). In this case, the interconnects 125 can more effectively shield the interconnects 115 from the noise, thereby further improving the noise resistance.

Further, the determination unit 151 may determine whether or not an abnormality is generated in one of the plurality of second interconnects (125, 148B), based on the real components and the imaginary components obtained by digitally converting the electrostatic capacitances of the plurality of sensor electrodes 110 and demodulating the digitally converted electrostatic capacitances with the demodulated signal having a frequency identical to that of the AC signal. In this case, it is possible to determine the interconnect 125 in which the abnormality is generated, based on a change in the impedance of one of the plurality of interconnects 125.

The determination unit 151 may determine whether the hand H is in contact with the outer skin covering the plurality of sensor electrodes 110, based on the real components and the imaginary components. In this case, it is possible to provide the electrostatic detector 100 capable of determining whether or not the hand H is in contact with the outer skin of the rim 11 of the steering wheel 10 based on the real components and the imaginary components, and capable of determining the interconnect 125 in which the abnormality, such as the disconnection or the like, is generated among the plurality of interconnects 125.

According to the present disclosure, it is possible to provide an electrostatic detector capable of determining which interconnect of a plurality of interconnects to a shield electrode includes an abnormality, such as the disconnection or the like.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electrostatic detector comprising:
a plurality of sensor electrodes;
a shield electrode coupled to the plurality of sensor electrodes;
a signal output unit configured to output an AC signal;
a plurality of first interconnects coupled to the plurality of sensor electrodes, respectively;
a plurality of second interconnects configured to couple the shield electrode to the signal output unit and supply the AC signal to the shield electrode, the plurality of second interconnects having mutually different resistance values between the shield electrode and the signal output unit; and
a determination unit coupled to the plurality of sensor electrodes via the plurality of first interconnects and configured to determine whether or not an abnormality is generated in a second interconnect of the plurality of second interconnects based on electrostatic capacitances of the plurality of sensor electrodes.

2. The electrostatic detector as claimed in claim 1, wherein at least a part of the plurality of second interconnects is a shield interconnect configured to shield at least a part of the plurality of first interconnects.

3. The electrostatic detector as claimed in claim 2, wherein a number of the plurality of second interconnects is equal to a number of the plurality of first interconnects.

4. The electrostatic detector as claimed in claim 2, wherein at least a part of the plurality of second interconnects covers and shields at least a part of the plurality of first interconnects.

5. The electrostatic detector as claimed in claim 1, wherein the determination unit determines whether or not an abnormality is generated in a second interconnect of the plurality of second interconnects, based on real components and imaginary components obtained by digitally converting electrostatic capacitances of the plurality of sensor electrodes and demodulating the digitally converted electrostatic capacitances with a demodulated signal having a frequency identical to that of the AC signal.

6. The electrostatic detector as claimed in claim 5, wherein the determination unit determines whether or not an object is in contact with a cover covering the plurality of sensor electrodes, based on the real components and the imaginary components.
